(19) United States
(12) Patent Application Publication
(10) Pub. No.: US 2024/0183628 A1
(43) Pub. Date: Jun. 6, 2024

(54) HEAT SINK

(71) Applicant: FURUKAWA ELECTRIC CO., LTD., Tokyo (JP)

(72) Inventors: Takahiro BANZAI, Tokyo (JP); Hirofumi AOKI, Tokyo (JP); Hideaki KAWABATA, Tokyo (JP); Kenya KAWABATA, Tokyo (JP)

(73) Assignee: FURUKAWA ELECTRIC CO., LTD., Tokyo (JP)

(21) Appl. No.: 18/437,647

(22) Filed: Feb. 9, 2024

Related U.S. Application Data
(63) Continuation of application No. PCT/JP2022/031291, filed on Aug. 19, 2022.

(30) Foreign Application Priority Data
Aug. 20, 2021 (JP) 2021-135155

(51) Int. Cl. F28F 9/26; F28F 9/00

(52) U.S. Cl. CPC F28F 9/262; F28F 2009/004; F28F 2210/08; F28F 2215/02; F28F 2250/04

(57) ABSTRACT

A heat sink includes: a container in which a cavity is formed, the container having a first principal surface and a second principal surface; a working fluid encapsulated in the cavity, and a steam flow path defined in the cavity, in which the container has a flat portion and a protruding part projecting from the flat portion, an inner space of the protruding part of the container is in communication with an inner space of the flat portion to form the cavity, the protruding part of the container includes a heat receiver that is to be thermally connected with a heating element that is a cooling target, and the flat portion of the container has an intermediate portion region continuous from the protruding part and a heat radiator region more distant from the protruding part than the intermediate portion region and thermally connected with a heat radiating fin.

### CROSS REFERENCE TO RELATED APPLICATIONS

The present application is a continuation application of International Patent Application No. PCT/JP2022/031291 filed on Aug. 19, 2022, which claims the benefit of Japanese Patent Application No. 2021-135155, filed on Aug. 20, 2021. The contents of these applications are incorporated herein by reference in their entirety.

### BACKGROUND

### Technical Field

The present disclosure relates to a heat sink that has an excellent heat transport performance and, consequently, exhibits an excellent cooling performance.

### Background

Electronic components, such as a semiconductor device, mounted on electric/electronic apparatuses experience an increase in heat generation amount due to an increase in functionality of the electronic components and the electronic components are mounted in close proximity. Accordingly, it has recently become increasingly important to cool the electronic components. According to a method employed as a method of cooling a heating element such as an electronic component disposed in a narrow space, heat of the electronic component or the like is radiated after transported to the outside of a board on which the electronic component and the like are mounted. A heat sink may be used as a cooling apparatus that radiates heat of an electronic component or the like after transporting the heat to the outside of a board, the heat sink including a plurality of heat pipes having one end that is thermally connected with the electronic component or the like and the other end provided with a heat radiating fin.

Specifically, a cooling apparatus is proposed, in which two heat pipes are drawn from a heat receiver being in contact with a circuit component on a circuit board to the outside of the circuit board, drawn heat-radiation-side end portions are thermally connected with respective different heat radiating fins and the heat radiating fins are cooled by a single fan disposed between the heat radiating fins (Japanese Patent Laid-Open No. 2001-217366).

However, in the cooling apparatus of Japanese Patent Laid-Open No. 2001-217366, the heat pipes each include a tubular container used as heat transport members and heat of a heating element, disposed on the circuit board, is transported to the outside of the circuit board by virtue of a heat transport function of the heat pipes. A heat transport amount during transport of heat to the outside of the circuit board is considerably dependent on a sectional area of the heat transport members in an orthogonal direction relative to a heat transport direction; therefore, Japanese Patent Laid-Open No. 2001-217366 is disadvantageous in that a cooling performance is not sufficient due to an insufficient heat transport amount during transport of heat to the outside of the circuit board.

In addition, the heating element such as an electronic component is mounted at a high density due to an increase in functionality of electric/electronic apparatuses, which causes various other components to be disposed in the vicinity of a cooling target, or the heating element such as an electronic component. Accordingly, to transport heat of the electronic component or the like to the outside of the board using the heat pipe, it is necessary to route the heat pipe in a manner allowing for avoiding other components disposed in the vicinity of the cooling target, or the heating element. The tubular container is usually bent in a height direction of the other components in a narrow space, causing the heat pipe to be routed while straddling the other components disposed in the vicinity of the cooling target, or the heating element, to avoid the other components.

However, bending the tubular container in the height direction of the other components causes a bent surface to be formed in a bent portion of the tubular container with a gap being made in the bent portion of the tubular container between the cooling target, or the heating element, and the heat pipe, which would result in a failure of achieving a sufficient thermal connectivity between the heating element and the heat pipe. In addition, in order to achieve thermal connectivity between the heating element and the heat pipe, it is discussed that no heat pipe is provided in a region where the other components are disposed instead of bending the heat pipe. However, in a case where no heat pipe is provided in the region where the other components are disposed, the installation number of heat pipes is reduced, which results in a failure of achieving a sufficient heat transport amount.

### SUMMARY

The present disclosure is related to providing a heat sink that exhibits an excellent cooling performance by virtue of an excellent thermal connectivity with a heating element and an excellent heat transport amount during transport of heat of a cooling target, or the heating element, even though another component is disposed in the vicinity of the cooling target, or the heating element.

One configuration of the present disclosure is as follows.

[1] A heat sink including:
a container in which a cavity is formed, the container having a first principal surface and a second principal surface opposite the first principal surface;
a working fluid encapsulated in the cavity, and
a steam flow path defined in the cavity and through which the working fluid in a gas phase flows, in which
the container has a flat portion and a protruding part projecting in an external direction from the flat portion,
an inner space of the protruding part of the container is in communication with an inner space of the flat portion to form the cavity,
the protruding part of the container includes a heat receiver that is to be thermally connected with a heating element that is a cooling target, and
the flat portion of the container has an intermediate portion region continuous from the protruding part and a heat radiator region more distant from the protruding part than the intermediate portion region and thermally connected with a heat radiating fin.

[2] The heat sink according to [1], in which the heat radiating fin includes a first heat radiating fin thermally connected with the first principal surface and a second heat radiating fin thermally connected with the second principal surface.

[3] The heat sink according to [1] or [2], in which the heat radiator region of the container is wider than the protruding part.

[4] The heat sink according to [3], in which the container has a part becoming wider as progress from the protruding part toward the heat radiator region.

[5] The heat sink according to [1] or [2], in which
the container is in a shape having a longitudinal direction and a lateral direction in plan view,
one end in the longitudinal direction of the container is provided with the protruding part, and
another end in the longitudinal direction of the container is the heat radiator region.

[6] The heat sink according to [1] or [2], in which
the container is in a shape having a longitudinal direction and a lateral direction in plan view,
a middle portion in the longitudinal direction of the container is provided with the protruding part, and
both ends in the longitudinal direction of the container are each the heat radiator region.

[7] The heat sink according to [1] or [2], wherein
the container has the protruding part in a middle portion of the container in plan view, and
a peripheral portion of the container in plan view is the heat radiator region.

[8] The heat sink according to [1] or [2], in which
the container is in a shape having a longitudinal direction and a lateral direction in plan view, the longitudinal direction having a bent portion,
the protruding part is provided in each of one end and another end in the longitudinal direction of the container, and
a middle portion in the longitudinal direction of the container is the heat radiator region.

[9] The heat sink according to [1] or [2], in which
the container includes one plate-shaped body and another plate-shaped body opposite the one plate-shaped body, and
the one plate-shaped body has the protruding part projecting in the external direction.

In the aspect of the heat sink of [1] above, a container has a flat portion and a protruding part projecting in an external direction from the flat portion and the protruding part includes a heat receiver that is to be thermally connected with a heating element. In addition, the flat portion has: a heat radiator region thermally connected with a heat radiating fin; and an intermediate portion region provided between the protruding part and the heat radiator, not thermally connected with the heating element, and continuous from the protruding part. The intermediate portion region of the container is a region where positive heat receiving is not to be performed. Thus, in the heat sink of [1] above, heat of the heating element is transported from the protruding part, or heat receiver, through the intermediate portion, or flat portion, to the heat radiator, or a flat portion region distant from the protruding part, and is radiated into an external environment at the heat radiator region.

In addition, in the aspect of the heat sink according to [1] above, the container has a first principal surface and a second principal surface opposite the first principal surface and a cavity is formed inside, the heat sink including a working fluid encapsulated in the cavity and a steam flow path defined in the cavity and through which the working fluid in a gas phase flows. Thus, in the aspect of the heat sink of [1] above, the container is in a flat shape and the inner space of the container, which exhibits a heat transport function, is in an interconnected integral form.

According to the aspect of the heat sink of the present disclosure, the container has the flat portion and the protruding part projecting in the external direction from the flat portion and the protruding part includes the heat receiver that is to be thermally connected with a cooling target, or the heating element, which allows the container to avoid, even though another component is disposed in the vicinity of the heating element, the other component in a height direction of the other component without the necessity of bending the container. In other words, in the aspect of the heat sink of the present disclosure, the flat portion has the intermediate portion region continuous from the protruding part, which allows the container to avoid, even though another component is disposed in the vicinity of the heating element, the other component in the height direction of the other component without the necessity of bending the container. Therefore, the heat sink of the present disclosure is excellent in thermal connectivity between the container and the heating element and, consequently, exhibits an excellent cooling performance. In addition, according to the aspect of the heat sink of the present disclosure, the inner space of the container is in the interconnected integral form with a sectional area of the container in an orthogonal direction relative to a heat transport direction being increased, which leads to an excellent heat transport amount. Therefore, according to the aspect of the heat sink of the present disclosure, the flat portion of the container has the intermediate portion region continuous from the protruding part and the heat radiator region more distant from the protruding part than the intermediate portion region and thermally connected with the heat radiating fin, which causes an excellent heat transport amount to be exhibited during transport of heat of the cooling target, or heating element, to the heat radiator through the intermediate portion to provide an excellent cooling performance.

According to the aspect of the heat sink of the present disclosure, the heat radiating fin includes a first heat radiating fin thermally connected with the first principal surface and a second heat radiating fin thermally connected with the second principal surface, which makes it possible to increase a fin area of the heat radiating fin and, consequently, exhibit a further excellent cooling performance. In addition, according to the aspect of the heat sink of the present disclosure, the heat radiating fin is thermally connected with the heat radiator of the container as being divided into the first heat radiating fin and the second heat radiating fin, which makes it possible to prevent creation of a region of the heat radiating fin not sufficiently contributable to heat radiation and improve the heat radiation efficiency of the heat radiating fin even though the fin area of the heat radiating fin is increased.

According to the aspect of the heat sink of the present disclosure, the heat radiator region of the container is wider than the protruding part, which makes it possible to increase the installation number of heat radiating fins and, consequently, exhibit a further excellent cooling performance.

According to the aspect of the heat sink of the present disclosure, the positions of the flat portion and the protruding part in the container are designed in accordance with the space where the heat sink is to be installed and disposition, heat generation amount, etc., of a heating element, which allows the positions of the heat receiver, the intermediate portion, and the heat radiator to be set. Therefore, the heat sink is excellent in design flexibility even for a heating element disposed in a narrow space.

### BRIEF DESCRIPTION OF THE DRAWINGS

FIG. 1 is a plan view of assistance in explaining the summary of a heat sink according to a first embodiment of the present disclosure;

FIG. 2 is a side view of assistance in explaining the summary of the heat sink according to the first embodiment of the present disclosure;

FIG. 3 is a plan view of assistance in explaining the summary of a heat sink according to a second embodiment of the present disclosure;

FIG. 4 is a side view of assistance in explaining the summary of the heat sink according to the second embodiment of the present disclosure;

FIG. 5 is a plan view of assistance in explaining the summary of a heat sink according to a third embodiment of the present disclosure;

FIG. 6 is a side view of assistance in explaining the summary of the heat sink according to the third embodiment of the present disclosure;

FIG. 7 is a plan view of assistance in explaining the summary of a heat sink according to a fourth embodiment of the present disclosure;

FIG. 8 is a side view of assistance in explaining the summary of the heat sink according to the fourth embodiment of the present disclosure;

FIG. 9 is a plan view of assistance in explaining the summary of a heat sink according to a fifth embodiment of the present disclosure;

FIG. 10 is a side view of assistance in explaining the summary of the heat sink according to the fifth embodiment of the present disclosure;

FIG. 11 is a plan view of assistance in explaining the summary of a heat sink according to a sixth embodiment of the present disclosure;

FIG. 12 is a side view of assistance in explaining the summary of the heat sink according to the sixth embodiment of the present disclosure;

FIG. 13 is a plan view of assistance in explaining the summary of a heat sink according to a seventh embodiment of the present disclosure; and

FIG. 14 is a side view of assistance in explaining the summary of the heat sink according to the seventh embodiment of the present disclosure.

### DETAILED DESCRIPTION

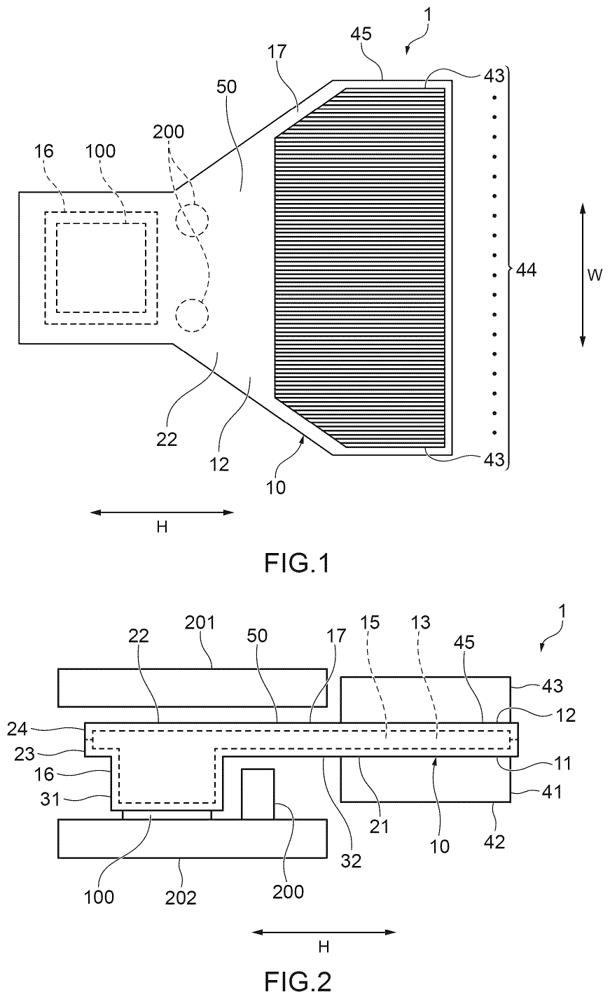

Hereinafter, a detailed description will be made on a heat sink according to a first embodiment of the present disclosure. FIG. 1 is a plan view of assistance in explaining the summary of the heat sink according to the first embodiment of the present disclosure. FIG. 2 is a side view of assistance in explaining the summary of the heat sink according to the first embodiment of the present disclosure.

As illustrated in FIGS. 1 and 2, a heat sink 1 according to the first embodiment of the present disclosure includes a container 10 in which a cavity 13 is formed by stacking opposite two plate-shaped bodies, that is, one plate-shaped body 11 and the other plate-shaped body 12 opposite the one plate-shaped body 11, a working fluid (not illustrated) encapsulated in the cavity 13, and a steam flow path 15 defined in the cavity 13 and through which the working fluid in a gas phase flows. A heat transport portion of the heat sink 1 is formed by the container 10 in which the cavity 13 is formed, the working fluid, and the steam flow path 15.

The container 10 is a thin flat container, where the one plate-shaped body 11 has a first principal surface, or first surface 21, and the other plate-shaped body 12 has a second principal surface, or second surface 22. Thus, the container 10, in which the cavity 13 is formed, has the first principal surface, or first surface 21, and the second principal surface, or second surface 22, opposite the first surface 21.

The first surface 21 has a flattened flat part 32 and a protruding part 31 projecting from the flat part 32 in an external direction. In the heat sink 1, the single protruding part 31 is provided in the first surface 21 of the container 10 at an end in a heat transport direction H of the container 10. In addition, a side surface of the protruding part 31 projects from the flat part 32 in a vertical direction. In contrast, the second surface 22 has no protruding part and the second surface 22 is in the form of a flattened flat part as a whole. With the first surface 21 having the flat part 32 and the protruding part 31 projecting from the flat part 32 in the external direction, the container 10 has a flat portion 17 and a protruding part 16 projecting from the flat portion 17 in the external direction. Thus, the one plate-shaped body 11 has the protruding part 16 projecting in the external direction. As is understood from the above, the flat portion 17 and the protruding part 16 of the container 10 are integrally molded. In addition, a side surface of the protruding part 16 projects from the flat portion 17 in the vertical direction. The single protruding part 16 is provided at the end of the first surface 21 of the container 10, whereas no protruding part is provided on the second surface 22.

In addition, a side wall 23 is erected on the one plate-shaped body 11 along a periphery of the first surface 21 and a side wall 24 is erected on the other plate-shaped body 12 along a periphery of the second surface 22. A distal edge of the side wall 23 of the one plate-shaped body 11 and a distal edge of the side wall 24 of the other plate-shaped body 12 are opposed and brought into contact with each other, whereby the inner space, or cavity 13, of the container 10 is formed. Thus, the side wall 23 and the side wall 24 form a side surface of the container 10. The cavity 13, which is a sealed space, is pressure-reduced by a deaeration treatment. An inner space of the protruding part 16 of the container 10 is in communication with an inner space of the flat portion 17 and the cavity 13 of the container 10 is formed by the inner space of the protruding part 16 and the inner space of the flat portion 17. Thus, the working fluid can flow between the inner space of the protruding part 16 and the inner space of the flat portion 17. In addition, the heat sink 1 includes the single container 10 and the inner space of the container 10, which exhibits a heat transport function, is in an interconnected integral form.

A shape of the container 10 is not limited to a particular one. In the heat sink 1, for example, the protruding part 16 is in a quadrangular shape and a flat portion 17 region of the container 10 is wider than the protruding part 16 in plan view (as seen from a vertical direction relative to the flat portion 17 of the container 10). More specifically, the container 10 has a part becoming wider as progress from the protruding part 16 toward the flat portion 17 region in plan view.

In the heat sink 1, a first heat radiating fin 41 is erected on, within the first surface 21 of the container 10, an exterior of the flat part 32 and the first heat radiating fin 41 is thermally connected with the container 10. The first heat radiating fin 41 is erected on, within the first surface 21 of the container 10, the other end in the heat transport direction H. The first heat radiating fin 41 includes a plurality of heat radiating fins arranged side by side at a predetermined interval along a width direction W of the container 10, that is, an orthogonal direction relative to the heat transport direction H of the container 10. The plurality of first heat radiating fins 41 are arranged side by side to form a first heat radiating fin group 42. In the heat sink 1, heights of the plurality of first heat radiating fins 41, 41, 41 . . . , which form the first heat radiating fin group 42, are all substantially the same. In addition, the heights of the first heat radiating fins 41 are equal to or lower than a height of the protruding part 16. In the heat sink 1, the heights of the first heat radiating fins 41 are set lower than the height of the protruding part 16 with distal ends of the first heat radiating fins 41 retreated in a direction toward the flat portion 17 of the container 10 with respect to a distal end of the protruding part 16.

In contrast, none of the first heat radiating fins 41 is provided within the first surface 21 of the container 10 either at the protruding part 16 located at one end in the heat transport direction H of the container 10 or in a middle portion in the heat transport direction H of the container 10.

As illustrated in FIGS. 1 and 2, the protruding part 16 of the container 10, which is a part with which a heating element 100 that is an object to be cooled is to be thermally connected, functions as a heat receiver of the heat sink 1. The heating element 100 is thermally connected with the distal end of the protruding part 16. As is understood from the above, the protruding part 16 includes the heat receiver with which the heating element 100 is to be thermally connected and the distal end of the protruding part 16, with which the heating element 100 is to be thermally connected, is provided with no heat radiating fin. Examples of the heating element 100 include an electronic component such as a central processing unit mounted on a wiring board 202. By virtue of the distal ends of the first heat radiating fins 41 being located in a direction toward the flat portion 17 of the container 10 with respect to the distal end of the protruding part 16, the heating element 100 can be thermally connected with the distal end of the protruding part 16 without interference with the first heat radiating fins 41 even though the heating element 100 is mounted on the wiring board 202.

The second surface 22 is provided with no protruding part, being in the form of a flat surface as a whole. A second heat radiating fin 43 is erected on an exterior of the second surface 22 and the second heat radiating fin 43 is thermally connected with the container 10. The second heat radiating fin 43 is erected on, within the second surface 22 of the container 10, the other end in the heat transport direction H. Thus, the second heat radiating fin 43 is disposed opposite the first heat radiating fin 41 with the other end of the container 10 in between. In addition, the second heat radiating fin 43 is erected on the exterior of the second surface 22 such that a principal surface of the second heat radiating fin 43 is substantially parallel with a principal surface of the first heat radiating fin 41. In addition, the second heat radiating fin 43 includes a plurality of fins arranged side by side at a predetermined interval along the width direction W of the container 10. The plurality of second heat radiating fins 43 are arranged side by side to form a second heat radiating fin group 44. In the heat sink 1, heights of the plurality of second heat radiating fins 43, 43, 43 . . . , which form the second heat radiating fin group 44, are all substantially the same.

As is understood from the above, the container 10 has the other end in the heat transport direction H, where the heat radiating fins are thermally connected with the first surface 21 and the second surface 22, i.e., both surfaces of the plate-shaped container 10. As is understood from the above, the heat radiating fins are thermally connected with the container 10 as being divided between both surfaces (i.e., the first surface 21 and the second surface 22) of the container 10 at the other end in the heat transport direction H of the container 10. The other end in the heat transport direction H of the container 10 with which the first heat radiating fins 41 and the second heat radiating fins 43 are thermally connected serves as a region 45 as a heat radiator of the heat sink 1.

In contrast, none of the second heat radiating fins 43 is provided within the second surface 22 of the container 10 either at the one end in the heat transport direction H of the container 10 or in the middle portion in the heat transport direction H of the container 10. As is understood from the above, no heat radiating fin is provided within the container 10 either at the one end in the heat transport direction H of the container 10 where the protruding part 16 is provided or in the middle portion in the heat transport direction H of the container 10. In addition, the heating element 100, which is an object to be cooled, is not thermally connected with the second surface 22. It should be noted that the protruding part 16 is disposed within the one end of the first surface 21 in a direction offset toward the region 45 as the heat radiator with respect to the side wall 23 erected along the periphery of the first surface 21 in the heat sink 1. Thus, a portion between the side wall 23, which is erected along the periphery of the first surface 21, and the protruding part 16 within the one end of the first surface 21 is also the flat portion 17.

The flat portion 17 of the container 10 has the region 45 as the heat radiator thermally connected with the first heat radiating fins 41 and the second heat radiating fins 43 and a region 50 as an intermediate portion provided between the protruding part 16 and the region 45 as the heat radiator and thermally connected with neither the heating element 100 nor the heat radiating fins (the first heat radiating fins 41 and the second heat radiating fins 43). The region 50 as the intermediate portion is provided between the protruding part 16 of the container 10 and the region 45 as the heat radiator in the heat transport direction H. In the heat sink 1, the region 50 as the intermediate portion of the container 10 is a region where neither positive heat receiving nor heat radiation is to be performed. As is understood from the above, the region 50 as the intermediate portion of the container 10 functions as a heat insulator in the heat sink 1. Thus, in the heat sink 1, the flat portion 17 of the container 10 has the region 50 as the intermediate portion located on a side of the protruding part 16 and not thermally connected with the heat radiating fins and the region 45 as the heat radiator more distant from the protruding part 16 than the region 50 as the intermediate portion and thermally connected with the heat radiating fins.

The container 10 has a part becoming wider as progress toward the flat portion 17 region from the protruding part 16 in plan view; therefore, the region 45 as the heat radiator of the container 10 is wider than the protruding part 16 including the heat receiver and the container 10 has a part becoming wider as progress toward the region 45 as the heat radiator from the protruding part 16. In the heat sink 1, the region 50 as the intermediate portion becomes wider as progress toward the region 45 as the heat radiator from the protruding part 16.

In the heat sink 1, heat of the heating element 100 is transported from the heat receiver, or protruding part 16, through the region 50 as the intermediate portion close to the protruding part 16 within the flat portion 17 to the region 45 as the heat radiator distant from the protruding part 16 within the flat portion 17 and is radiated into an external environment at the region 45 as the heat radiator.

A wick structure (not illustrated) that generates a capillary force is provided in the cavity 13 of the container 10. The wick structure is provided, for example, across the container 10. The capillary force of the wick structure causes the working fluid, which has undergone a phase change from gas phase to liquid phase through the region 45 as the heat radiator of the container 10, to circulate from the region 45 as the heat radiator of the container 10 to the protruding part 16 including the heat receiver. Examples of the wick structure can include, without limitation, a sintered compact of metal powder such as copper powder, a metal mesh of a metallic wire, unwoven cloth, and a groove (a plurality of narrow grooves) formed in an interior of the container 10 and a combination thereof. In addition, a heat receiving part of the protruding part 16, with which the heating element 100 is to be connected, that is, a bottom of the protruding part 16, is provided with, as the wick structure, a first wick structure having a large capillary force, which makes it possible to prevent dry-out. In contrast, a part of the protruding part 16 other than the bottom, for example, the side surface of the protruding part 16 of the container 10 and the flat portion 17 of the container 10 or the side surface of the container 10, is provided with, as the wick structure, a second wick structure having a smaller capillary force than the first wick structure, which makes it possible to reduce a flow path resistance during circulation of the working fluid in the liquid phase. In a case where the wick structure is, for example, a sintered compact of metal powder, an average primary particle diameter of a material of the first wick structure, or metal powder, may be in a range from 1.0 nm to 10 μm and an average primary particle diameter of a material of the second wick structure, or metal powder, is in a range from 50 μm to 300 μm.

The steam flow path 15, which is an inner space of the container 10, extends across the container 10. Thus, the working fluid in the gas phase can flow across the container 10 by virtue of the steam flow path 15. In addition, a pillar (not illustrated) may be provided in the steam flow path 15 in order to maintain the inner space of the container 10, if necessary. In order to reduce the flow path resistance during circulation of the working fluid in the liquid phase, examples of the pillar can include, without limitation, a composite pillar including a columnar metal member (for example, a copper member) circumferentially covered with a wick structure and a columnar sintered compact of metal powder such as copper powder.

Examples of a material of the container 10 can include stainless steel, copper, copper alloy, aluminum, aluminum alloy, tin, tin alloy, titanium, titanium alloy, nickel, and nickel alloy. Examples of materials of the first heat radiating fins 41 and the second heat radiating fins 43 include, without limitation, metal materials such as copper, copper alloy, aluminum, and aluminum alloy, carbon materials such as graphite, and composite members including a carbon material.

The working fluid encapsulated in the cavity 13 can be selected as desired in accordance with compatibility with the material of the container 10. Examples of the working fluid can include water, fluorocarbons, cyclopentane, and ethylene glycol. The above examples may be used alone or a combination of two or more of the examples may be used in combination.

In addition, the heat sink 1 may be forcedly air-cooled using a blast fan (not illustrated), if necessary. A cooling air from the blast fan is supplied along the principal surfaces of the first heat radiating fins 41 and the second heat radiating fins 43, whereby cooling of the first heat radiating fin group 42 and the second heat radiating fin group 44 is accelerated.

Thereafter, description will be made on a mechanism of a cooling function of the heat sink 1. First, the heating element 100, which is an object to be cooled, is thermally connected with the distal end of the protruding part 16 of the container 10. With the container 10 receiving heat from the heating element 100 at the protruding part 16, the heat is transferred, at the protruding part 16 of the container 10, from the heating element 100 to the working fluid in the liquid phase in the cavity 13, causing a phase change from the working fluid in the liquid phase to the working fluid in the gas phase. The working fluid in the gas phase flows through the steam flow path 15 from the protruding part 16 of the container 10 through the region 50 as the intermediate portion of the flat portion 17 continuous with the protruding part 16 into the region 45 as the heat radiator of the flat portion 17. As the working fluid in the gas phase passes the region 50 as the intermediate portion of the flat portion 17 from the protruding part 16 of the container 10, flowing into the region 45 as the heat radiator of the flat portion 17, the heat from the heating element 100 is transported from the protruding part 16 of the container 10 to the region 45 as the heat radiator. The working fluid in the gas phase flowing from the protruding part 16 into the region 45 as the heat radiator radiates latent heat by virtue of a heat exchange effect of the first heat radiating fin group 42 and the second heat radiating fin group 44, undergoing a phase change from the gas phase to the liquid phase. The radiated latent heat is transferred to the first heat radiating fin group 42 and the second heat radiating fin group 44 thermally connected with the region 45 as the heat radiator of the container 10. The heat transferred from the container 10 to the first heat radiating fin group 42 and the second heat radiating fin group 44 is discharged to an external environment of the heat sink 1 through the first heat radiating fin group 42 and the second heat radiating fin group 44. The capillary force of the wick structure provided in the container 10 causes the working fluid, which has radiated the latent heat to undergone the phase change from the gas phase to the liquid phase, to circulate from the region 45 as the heat radiator of the container 10 through the region 50 as the intermediate portion to the protruding part 16.

In the heat sink 1 according to the first embodiment of the present disclosure, the container 10 has the flat portion 17 and the protruding part 16 projecting from the flat portion 17 in the external direction and the protruding part 16 includes the heat receiver that is to be thermally connected with a cooling target, or the heating element 100. Thus, even though another component 200 mounted on the wiring board 202 is disposed in the vicinity of the heating element 100 or an obstacle 201 is placed above the heating element 100 or the other component 200, the container 10 is allowed to avoid the other component 200 in a height direction of the other component 200 without the necessity of bending the container 10. In other words, the flat portion 17 has the region 50 as the intermediate portion continuous from the protruding part 16 in the heat sink 1, which causes the region 50 as the intermediate portion to function as an avoidance portion for avoiding the other component 200. Thus, even though the other component 200 or the obstacle 201 is disposed in the vicinity of the heating element 100, the container 10 is allowed to avoid the other component 200 in the height direction of the other component 200 without the necessity of bending the container 10. Therefore, the heat sink 1 is excellent in thermal connectivity between the container 10 and the heating element 100 and, consequently, exhibits an excellent cooling performance.

In addition, the inner space of the container 10 is in the interconnected integral form in the heat sink 1 with the sectional area of the container 10 in the orthogonal direction relative to the heat transport direction H being increased, which leads to an excellent heat transport amount. Accordingly, in the heat sink 1, the flat portion 17 of the container 10 has the region 50 as the intermediate portion which is located on the side of the protruding part 16, is not thermally connected with the heat radiating fins, and functions as the avoidance portion for avoiding the other component 200 and the region 45 as the heat radiator more distant from the protruding part 16 than the region 50 as the intermediate portion and thermally connected with the heat radiating fins (the first heat radiating fins 41 and the second heat radiating fins 43). This causes an excellent heat transport amount to be exhibited during transport of the heat of the cooling target, or heating element 100, to the region 45 as the heat radiator through the region 50 as the intermediate portion to provide an excellent cooling performance.

In addition, in the heat sink 1, the heat radiating fins include the first heat radiating fins 41 thermally connected with the first principal surface 21 and the second heat radiating fins 43 thermally connected with the second principal surface 22, which makes it possible to increase a fin area of the heat radiating fins and, consequently, exhibit a further excellent cooling performance. In addition, in the heat sink 1, the heat radiating fins are thermally connected with the region 45 as the heat radiator of the container 10 as being divided into the first heat radiating fins 41 and the second heat radiating fins 43, which makes it possible to prevent creation of a region of the heat radiating fins not sufficiently contributable to heat radiation and improve the heat radiation efficiency of the heat radiating fins even though the fin area of the heat radiating fins is increased.

In addition, in the heat sink 1, the region 45 as the heat radiator of the container 10 is wider than the protruding part 16, which makes it possible to increase the installation number of the first heat radiating fins 41 and the second heat radiating fins 43 and, consequently, exhibit a further excellent cooling performance. In addition, in the heat sink 1, the region 50 as the intermediate portion becomes wider as progress toward the region 45 as the heat radiator from the protruding part 16, which makes it possible to further improve the amount of heat transport from the protruding part 16 to the region 45 as the heat radiator.

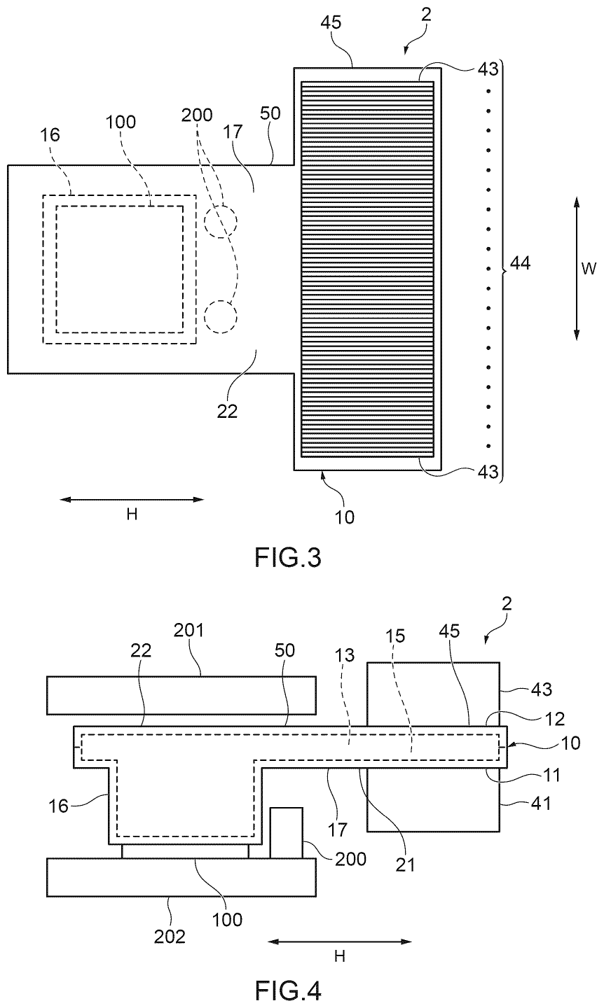

Thereafter, a detailed description will be made on a heat sink according to a second embodiment of the present disclosure. Main elements are common to the heat sink according to the second embodiment and the heat sink according to the first embodiment, so that the description will be made by using the same reference numeral to refer to the same element as that of the heat sink according to the first embodiment. FIG. 3 is a plan view of assistance in explaining the summary of the heat sink according to the second embodiment of the present disclosure. FIG. 4 is a side view of assistance in explaining the summary of the heat sink according to the second embodiment of the present disclosure.

In the heat sink 1 according to the first embodiment, the container 10 had the region 50 as the intermediate portion becoming wider as progress toward the region 45 as the heat radiator from the protruding part 16 in plan view. Instead of that, in a heat sink 2 according to the second embodiment of the present disclosure, in terms of a dimension of the container 10 in the orthogonal direction relative to the heat transport direction H, i.e., in the width direction W, the protruding part 16 and the region 50 as the intermediate portion are substantially the same and the region 45 as the heat radiator is wider as compared with the region 50 as the intermediate portion as illustrated in FIGS. 3, 4. In the heat sink 2, the shape of the container 10 is a T-shape in plan view.

Likewise, in the heat sink 2 according to the second embodiment, the region 45 as the heat radiator of the container 10 is wider than the protruding part 16, which makes it possible to increase the installation number of the first heat radiating fins 41 and the second heat radiating fins 43 and, consequently, exhibit a further excellent cooling performance. In addition, the heat sink 2 is allowed to be thermally connected with the heating element 100 and cool the heating element 100 even though the region 50 as the intermediate portion is a narrower space that is not allowed to be wider than the protruding part 16.

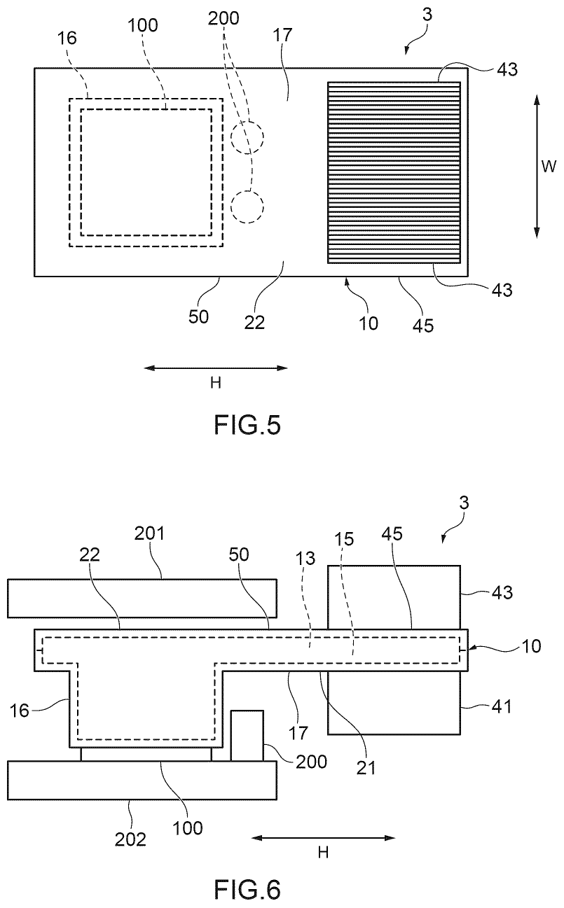

Thereafter, a detailed description will be made on a heat sink according to a third embodiment of the present disclosure. Main elements are common to the heat sink according to the third embodiment and the heat sinks according to the first and second embodiments, so that the description will be made by using the same reference numeral to refer to the same element as those of the heat sinks according to the first and second embodiments. FIG. 5 is a plan view of assistance in explaining the summary of the heat sink according to the third embodiment of the present disclosure. FIG. 6 is a side view of assistance in explaining the summary of the heat sink according to the third embodiment of the present disclosure.

In the heat sink 1 according to the first embodiment, the container 10 had the region 50 as the intermediate portion becoming wider as progress toward the region 45 as the heat radiator from the protruding part 16 in plan view. Instead of that, in a heat sink 3 according to the third embodiment of the present disclosure, in terms of a dimension of the container 10 in the orthogonal direction relative to the heat transport direction H, i.e., in the width direction W, all of the protruding part 16, the region 50 as the intermediate portion, and the region 45 as the heat radiator are substantially the same as illustrated in FIGS. 5, 6. In the heat sink 3, the container 10 is in a shape having a longitudinal direction and a lateral direction in plan view, specifically, in a rectangular shape in plan view.

The protruding part 16 with which the heating element 100 is to be thermally connected is provided at one end in the longitudinal direction of the container 10, whereas the other end in the longitudinal direction of the container 10 is the region 45 as the heat radiator thermally connected with the first heat radiating fins 41 and the second heat radiating fins 43. A middle portion in the longitudinal direction of the container 10 is thermally connected with neither the heating element 100 nor the heat radiating fins and is the region 50 as the intermediate portion functioning as the avoidance portion for avoiding the other component 200.

The heat sink 3 is allowed to be thermally connected with the heating element 100 and cool the heating element 100 even though the region 45 as the heat radiator and the region 50 as the intermediate portion are narrower spaces that are not allowed to be wider than the protruding part 16.

Likewise, in the heat sink 3, even though the other component 200 mounted on the wiring board 202 is disposed in the vicinity of the heating element 100 or the obstacle 201 is placed above the heating element 100 or the other component 200, the container 10 is allowed to avoid the other component 200 in the height direction of the other component 200 without the necessity of bending the container 10 by virtue of providing the protruding part 16. In other words, in the heat sink 3, the flat portion 17 likewise has the region 50 as the intermediate portion continuous from the protruding part 16, which causes the region 50 as the intermediate portion to function as the avoidance portion for avoiding the other component 200. Thus, even though the other component 200 or the obstacle 201 is disposed in the vicinity of the heating element 100, the container 10 is allowed to avoid the other component 200 in the height direction of the other component 200 without the necessity of bending the container 10. Therefore, the thermal connectivity between the container 10 and the heating element 100 is excellent and an excellent cooling performance is provided. In addition, in the heat sink 3, the inner space of the container 10 is likewise in the interconnected integral form with the sectional area of the container 10 in the orthogonal direction relative to the heat transport direction H being increased, which causes an excellent heat transport amount to be exhibited during transport of the heat of a cooling target, or the heating element 100, from the protruding part 16 through the region 50 as the intermediate portion to the region 45 as the heat radiator to provide an excellent cooling performance.

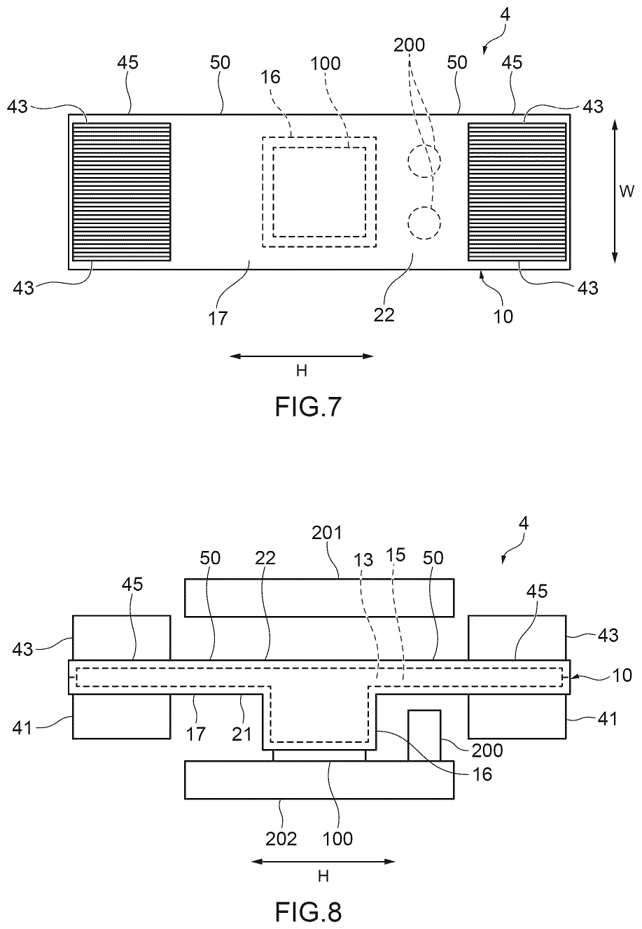

Thereafter, a detailed description will be made on a heat sink according to a fourth embodiment of the present disclosure. Main elements are common to the heat sink according to the fourth embodiment and the heat sinks according to the first through third embodiments, so that the description will be made by using the same reference numeral to refer to the same element as those of the heat sinks according to the first through third embodiments. FIG. 7 is a plan view of assistance in explaining the summary of the heat sink according to the fourth embodiment of the present disclosure. FIG. 8 is a side view of assistance in explaining the summary of the heat sink according to the fourth embodiment of the present disclosure.

In the heat sink 3 according to the third embodiment, the container 10 is in the rectangular shape having the longitudinal direction and the lateral direction in plan view, the one end in the longitudinal direction of the container 10 was provided with the protruding part 16 with which the heating element 100 was to be thermally connected, and the other end in the longitudinal direction of the container 10 was the region 45 as the heat radiator thermally connected with the first heat radiating fins 41 and the second heat radiating fins 43. Instead of that, as illustrated in FIGS. 7, 8, in a heat sink 4 according to the fourth embodiment, the container 10 is in a shape having a longitudinal direction and a lateral direction in plan view, the middle portion in the longitudinal direction of the container 10 is provided with the single protruding part 16, and both ends in the longitudinal direction of the container 10 are the regions 45 as the heat radiators. Thus, the first heat radiating fins 41 and the second heat radiating fins 43 are thermally connected with each of both ends in the longitudinal direction of the container 10.

In the heat sink 4, in terms of a dimension of the container 10 in the orthogonal direction relative to the heat transport direction H, i.e., in the width direction W, all of the protruding part 16, the region 50 as the intermediate portion, and the region 45 as the heat radiator are substantially the same. Specifically, in the heat sink 4, the container 10 is in a rectangular shape in plan view.

In the heat sink 4, both ends in the longitudinal direction of the container 10 are the regions 45 as the heat radiators. Thus, the single container 10 is provided with the two regions 45 as the heat radiators in the heat sink 4. In addition, the middle portion in the longitudinal direction of the container 10 is provided with the single protruding part 16 and both ends in the longitudinal direction of the container 10 are the regions 45 as the heat radiators. Thus, the two regions 50 as the intermediate portions are formed between the protruding part 16 and the regions 45 as the heat radiators.

In the heat sink 4, the two regions 45 as the heat radiators are provided in the single container 10, which makes it possible to sufficiently cool the heating element 100 irrespective of a further increase in heat generation amount of the heating element 100.

Likewise, in the heat sink 4, even though the other component 200 mounted on the wiring board 202 is disposed in the vicinity of the heating element 100 or the obstacle 201 is placed above the heating element 100 or the other component 200, the container 10 is allowed to avoid the other component 200 in the height direction of the other component 200 without the necessity of bending the container 10 by virtue of providing the protruding part 16. In other words, in the heat sink 4, the flat portion 17 likewise has the region 50 as the intermediate portion continuous from the protruding part 16, which causes the region 50 as the intermediate portion to function as the avoidance portion for avoiding the other component 200. Thus, even though the other component 200 or the obstacle 201 is disposed in the vicinity of the heating element 100, the container 10 is allowed to avoid the other component 200 in the height direction of the other component 200 without the necessity of bending the container 10. Therefore, the thermal connectivity between the container 10 and the heating element 100 is excellent and an excellent cooling performance is provided. In addition, in the heat sink 4, the inner space of the container 10 is likewise in the interconnected integral form with the sectional area of the container 10 in the orthogonal direction relative to the heat transport direction H being increased, which causes an excellent heat transport amount to be exhibited during transport of the heat of a cooling target, or the heating element 100, from the protruding part 16 through the two regions 50 as the intermediate portions to the two regions 45 as the heat radiators to provide an excellent cooling performance.

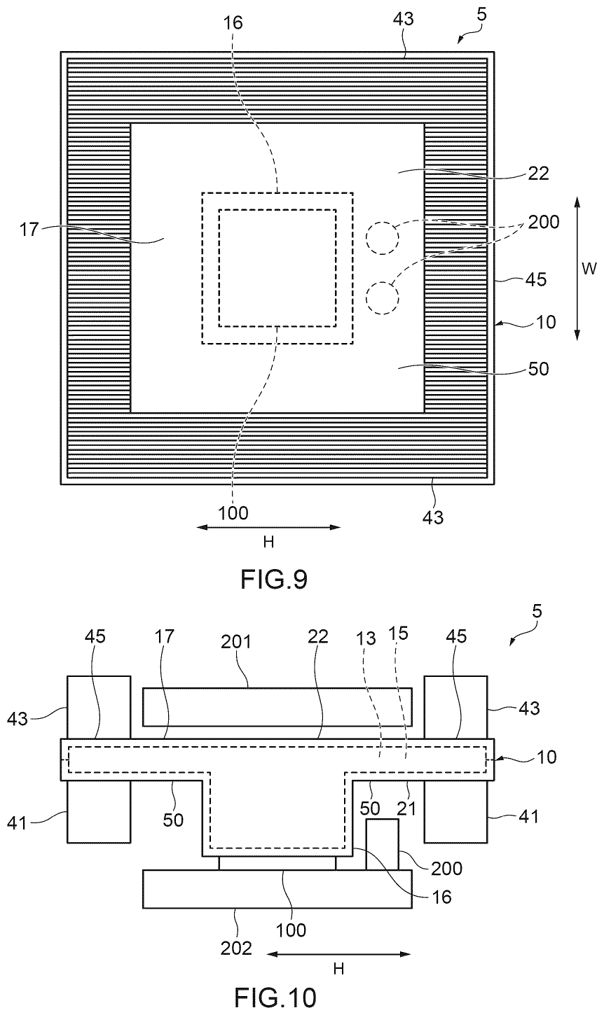

Thereafter, a detailed description will be made on a heat sink according to a fifth embodiment of the present disclosure. Main elements are common to the heat sink according to the fifth embodiment and the heat sinks according to the first through fourth embodiments, so that the description will be made by using the same reference numeral to refer to the same element as those of the heat sinks according to the first through fourth embodiments. FIG. 9 is a plan view of assistance in explaining the summary of the heat sink according to the fifth embodiment of the present disclosure. FIG. 10 is a side view of assistance in explaining the summary of the heat sink according to the fifth embodiment of the present disclosure.

In the heat sink 3 according to the third embodiment, the container 10 is in the rectangular shape having the longitudinal direction and the lateral direction in plan view, the one end in the longitudinal direction of the container 10 is provided with the protruding part 16 with which the heating element 100 was to be thermally connected, and the other end in the longitudinal direction of the container 10 was the region 45 as the heat radiator thermally connected with the first heat radiating fins 41 and the second heat radiating fins 43. Instead of that, as illustrated in FIGS. 9, 10, in a heat sink 5 according to the fifth embodiment, the container 10 has the single protruding part 16 in the middle portion of the container 10 in plan view and a peripheral portion of the container 10 in plan view is the region 45 as the heat radiator. A shape of the container 10 has neither a longitudinal direction nor a lateral direction in plan view and is a square in plan view.

In the heat sink 5, the region 45 as the heat radiator is provided at the four sides of the square, being in a form to fully surround the protruding part 16. The first heat radiating fins 41 and the second heat radiating fins 43 are thermally connected with the whole of the peripheral portion of the container 10 in plan view, which causes the whole of the peripheral portion of the container 10 in plan view to be the region 45 as the heat radiator. The region 50 as the intermediate portion is formed between the protruding part 16 located in the middle portion of the container 10 in plan view and the region 45 as the heat radiator located in the peripheral portion of the container 10 in plan view. The region 50 as the intermediate portion is thus in the form to fully surround the protruding part 16.

In the heat sink 5, the whole of the peripheral portion of the container 10 in plan view is the region 45 as the heat radiator, which makes it possible to sufficiently cool the heating element 100 irrespective of a further increase in heat generation amount of the heating element 100.

Likewise, in the heat sink 5, even though the other component 200 mounted on the wiring board 202 is disposed in the vicinity of the heating element 100 or the obstacle 201 is placed above the heating element 100 or the other component 200, the container 10 is allowed to avoid the other component 200 in the height direction of the other component 200 without the necessity of bending the container 10 by virtue of providing the protruding part 16. In other words, in the heat sink 5, the flat portion 17 likewise has the region 50 as the intermediate portion continuous from the protruding part 16, which causes the region 50 as the intermediate portion to function as the avoidance portion for avoiding the other component 200. Thus, even though the other component 200 or the obstacle 201 is disposed in the vicinity of the heating element 100, the container 10 is allowed to avoid the other component 200 in the height direction of the other component 200 without the necessity of bending the container 10. Therefore, the thermal connectivity between the container 10 and the heating element 100 is excellent and an excellent cooling performance is provided. In addition, in the heat sink 5, the inner space of the container 10 is likewise in the interconnected integral form with the sectional area of the container 10 in the orthogonal direction relative to the heat transport direction H being increased, which causes an excellent heat transport amount to be exhibited during transport of the heat of a cooling target, or the heating element 100, from the protruding part 16 through the region 50 as the intermediate portion around the protruding part 16 to the region 45 as the heat radiator to provide an excellent cooling performance.

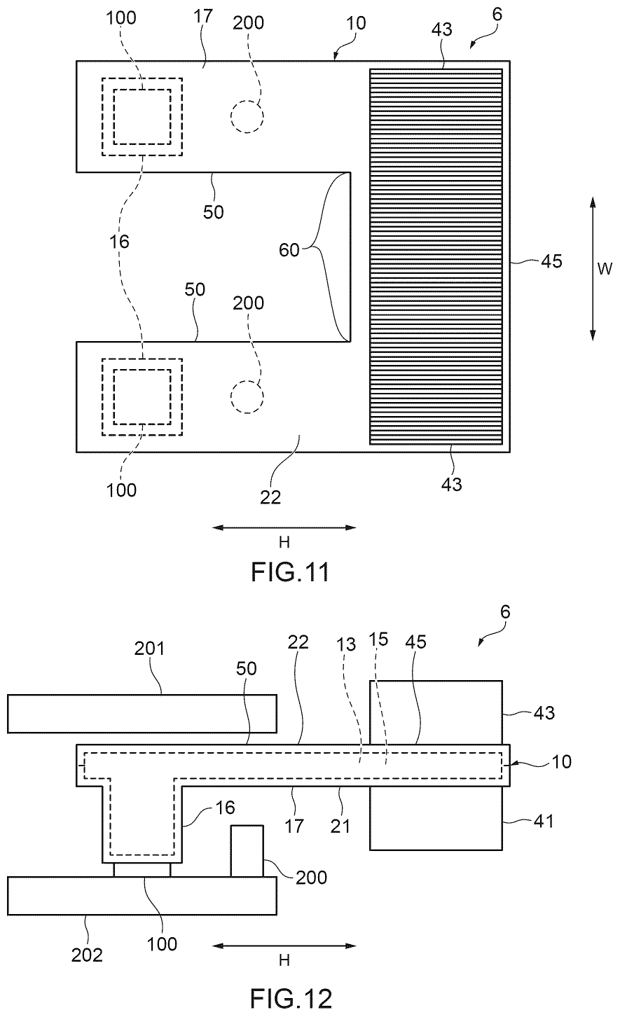

Thereafter, a detailed description will be made on a heat sink according to a sixth embodiment of the present disclosure. Main elements are common to the heat sink according to the sixth embodiment and the heat sinks according to the first through fifth embodiments, so that the description will be made by using the same reference numeral to refer to the same element as those of the heat sinks according to the first through fifth embodiments. FIG. 11 is a plan view of assistance in explaining the summary of the heat sink according to the sixth embodiment of the present disclosure. FIG. 12 is a side view of assistance in explaining the summary of the heat sink according to the sixth embodiment of the present disclosure.

In the heat sinks according to the above embodiments, the region 45 as the heat radiator was provided in the end portion of the container 10. Instead of that, in a heat sink 6 according to the sixth embodiment, the middle portion in the longitudinal direction of the container 10 is the region 45 as the heat radiator as illustrated in FIGS. 11, 12. In addition, in the heat sinks according to the above embodiments, the container 10 had the single protruding part 16. Instead of that, in the heat sink 6 according to the sixth embodiment, the container 10 includes a plurality of protruding parts 16 (two of them in the heat sink 6) as illustrated in FIGS. 11, 12.

Specifically, in the heat sink 6, the container 10 is in a shape having a longitudinal direction and a lateral direction in plan view, the longitudinal direction has a bent portion 60, and each of one end and the other end in the longitudinal direction of the container 10 is provided with the protruding part 16 with which the heating element 100 is to be thermally connected. In addition, the first heat radiating fins 41 and the second heat radiating fins 43 are thermally connected with the middle portion in the longitudinal direction of the container 10. Thus, the middle portion in the longitudinal direction of the container 10 is the region 45 as the heat radiator. In the heat sink 6, the shape of the container 10 is a U-shape in plan view. In other words, the container 10 has the region 45 as the heat radiator and extended portions extending in a vertical direction relative to a stretch direction of the region 45 as the heat radiator from respective both end portions of the region 45 as the heat radiator.

In the heat sink 6, the respective protruding parts 16 are provided in distal end portions of the two extended portions of the container 10 and the regions 50 as the intermediate portions are formed between the protruding parts 16 provided in the distal end portions of the extended portions and the region 45 as the heat radiator. As is understood from the above, the two regions 50 as the intermediate portions are formed. The heat sink 6 is in a form where the regions 50 as the intermediate portions are formed between the protruding parts 16 provided in the distal end portions of the extended portions and the bent portion 60.

In the heat sink 6, the container 10 has the plurality of protruding parts 16, which allows the single container 10 to cool a plurality of heating elements 100. In addition, the container 10 is in the shape having the bent portion 60 in the longitudinal direction, which allows the heat sink 6 to be installed even in a narrow space.

Likewise, in the heat sink 6, even though the other component 200 mounted on the wiring board 202 is disposed in the vicinity of the heating element 100 or the obstacle 201 is placed above the heating element 100 or the other component 200, the container 10 is allowed to avoid the other component 200 in the height direction of the other component 200 without the necessity of bending the container 10 by virtue of providing the protruding part 16. In other words, in the heat sink 6, the flat portion 17 likewise has the region 50 as the intermediate portion continuous from each of the protruding parts 16, which causes the region 50 as the intermediate portion to function as the avoidance portion for avoiding the other component 200. Thus, even though the other component 200 or the obstacle 201 is disposed in the vicinity of the heating element 100, the container 10 is allowed to avoid the other component 200 in the height direction of the other component 200 without the necessity of bending the container 10. Therefore, the thermal connectivity between the container 10 and the heating element 100 is excellent and an excellent cooling performance is provided. In addition, in the heat sink 6, the inner space of the container 10 is likewise in the interconnected integral form with the sectional area of the container 10 in the orthogonal direction relative to the heat transport direction H being increased, which causes an excellent heat transport amount to be exhibited during transport of the heat of a cooling target, or the two heating elements 100, from the two protruding parts 16 through the regions 50 as the intermediate portions to the region 45 as the heat radiator to provide an excellent cooling performance.

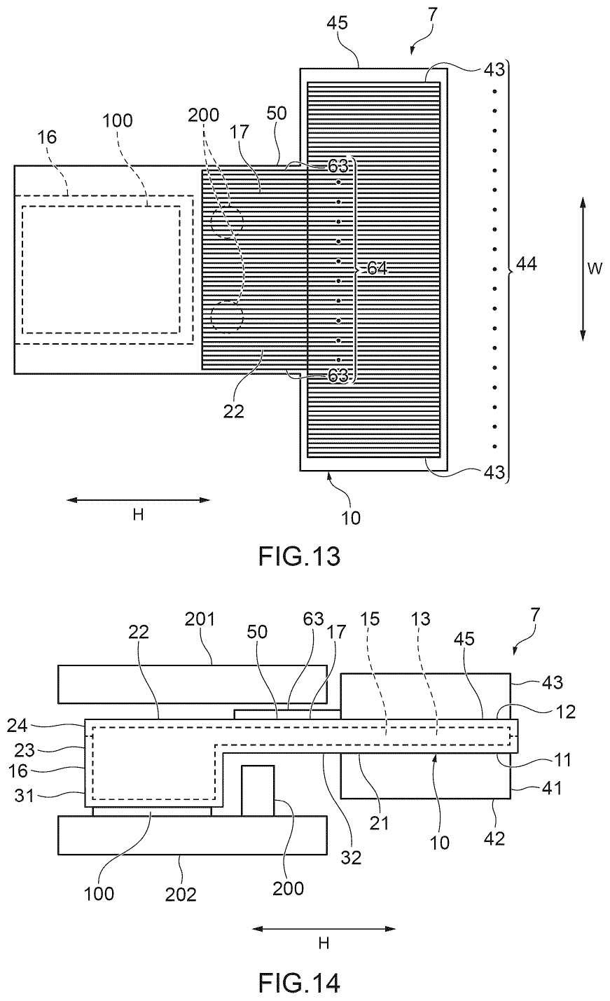

Thereafter, a detailed description will be made on a heat sink according to a seventh embodiment of the present disclosure. Main elements are common to the heat sink according to the seventh embodiment and the heat sinks according to the first through sixth embodiments, so that the description will be made by using the same reference numeral to refer to the same element as those of the heat sinks according to the first through sixth embodiments. FIG. 13 is a plan view of assistance in explaining the summary of the heat sink according to the seventh embodiment of the present disclosure. FIG. 14 is a side view of assistance in explaining the summary of the heat sink according to the seventh embodiment of the present disclosure.

In the heat sinks according to the above embodiments, no heat radiating fin was provided in the region 50 as the intermediate portion of the container 10. Instead of that, in a heat sink 7 according to the seventh embodiment, a third heat radiating fin 63 is provided in the region 50 as the intermediate portion of the container 10 as illustrated in FIGS. 13, 14. The heat sink 7 is in a form where the region 50 as the intermediate portion of the heat sink 2 according to the second embodiment is further provided with the third heat radiating fin 63. As is understood from the above, the region 50 as the intermediate portion of the container 10 functions as not a heat insulator but a heat radiator in the heat sink 7. Hence, in the heat sink of the present disclosure, a thermal function of the region 50 as the intermediate portion is not limited to a particular one, provided that the region 50 as the intermediate portion is allowed to avoid the other component 200.

In the heat sink 7, the third heat radiating fin 63 is provided on, within the region 50 as the intermediate portion, the second surface 22. In addition, the third heat radiating fin 63 is provided in a space between the second surface 22 and the obstacle 201 placed opposite the second surface 22.

The third heat radiating fin 63, which is provided between the second surface 22 and the obstacle 201, is a heat radiating fin having a height lower than the second heat radiating fins 43. The third heat radiating fin 63 includes a plurality of fins arranged side by side at a predetermined interval along the width direction W of the container 10. In addition, the plurality of third heat radiating fins 63 are arranged side by side to form a third heat radiating fin group 64. In the heat sink 7, heights of the plurality of third heat radiating fins 63, 63, 63 . . . , which form the third heat radiating fin group 64, are all substantially the same. In addition, the third heat radiating fins 63 may be in contact with the second heat radiating fins 43 or may be not in contact with the second heat radiating fins 43 with a gap in between. In the heat sink 7, the third heat radiating fins 63 are in a form being in contact with the second heat radiating fins 43.

Likewise, in the heat sink 7, in which the third heat radiating fins 63 are provided in the region 50 as the intermediate portion, the flat portion 17 has the region 50 as the intermediate portion continuous from the protruding part 16, which allows the region 50 as the intermediate portion to avoid the other component 200 and function as the avoidance portion for the other component 200.

In addition, in the heat sinks according to the above embodiments, the protruding part 16 was provided within the one end of the first surface 21 in the direction offset toward the region 45 as the heat radiator with respect to the side wall 23 erected along the periphery of the first surface 21. Instead of that, the heat sink 7 according to the seventh embodiment is in a form where the protruding part 16 extends even to, within the one end of the first surface 21, a part corresponding to the side wall 23 as illustrated in FIGS. 13, 14. Thus, in the heat sink 7, the protruding part 16 is formed in a direction toward the region 50 as the intermediate portion from the part corresponding to the side wall 23.

Likewise, in the heat sink 7, even though the other component 200 mounted on the wiring board 202 is disposed in the vicinity of the heating element 100 or the obstacle 201 is placed above the heating element 100 or the other component 200, the container 10 is allowed to avoid the other component 200 in the height direction of the other component 200 without the necessity of bending the container 10 by virtue of providing the protruding part 16. In other words, in the heat sink 7, the flat portion 17 likewise has the region 50 as the intermediate portion continuous from the protruding part 16, which causes the region 50 as the intermediate portion to function as the avoidance portion for avoiding the other component 200. Thus, even though the other component 200 or the obstacle 201 is disposed in the vicinity of the heating element 100, the container 10 is allowed to avoid the other component 200 in the height direction of the other component 200 without the necessity of bending the container 10. Therefore, the thermal connectivity between the container 10 and the heating element 100 is excellent and an excellent cooling performance is provided. In addition, in the heat sink 7, the inner space of the container 10 is likewise in the interconnected integral form with the sectional area of the container 10 in the orthogonal direction relative to the heat transport direction H being increased, which causes an excellent heat transport amount to be exhibited during transport of the heat of a cooling target, or the two heating elements 100, from the two protruding parts 16 through the regions 50 as the intermediate portions to the region 45 as the heat radiator to provide an excellent cooling performance.

In addition, in the heat sink 7, the region 50 as the intermediate portion is further provided with the third heat radiating fins 63, which allows the region 50 as the intermediate portion to function as a heat radiator to further improve the heat radiation performance. In addition, in the heat sink 7, the protruding part 16 extends even to, within the one end of the first surface 21, the part corresponding to the side wall 23, which provides an excellent thermal connectivity even with a large-sized heating element 100.

As is understood from the above embodiments, in the heat sink of the present disclosure, the positions of the flat portion and the protruding part in the container are designed in accordance with the space where the heat sink is to be installed and deposition, heat generation amount, etc., of a heating element, which allows the positions of the heat receiver, the intermediate portion, and the heat radiator to be set. Therefore, the heat sink is excellent in design flexibility even for a heating element installed in a narrow space.

Thereafter, description will be made on other embodiments of the present disclosure. In the heat sinks of the above embodiments, the first heat radiating fins were erected on the first surface of the container and the second heat radiating fins were erected on the second surface; however, the heat radiating fins may be erected on only one of the first surface and the second surface in some forms.

In the heat sinks according to the third and fourth embodiments, the shape of the container having the longitudinal direction and the lateral direction in plan view was a quadrangular shape; however, the shape of the container having the longitudinal direction and the lateral direction is not limited to a particular one and may be a pentagonal shape or a polygonal shape having more corners than the pentagonal shape, an oval shape, or the like in plan view. In addition, in the heat sink according to the fifth embodiment, the shape of the container having neither the longitudinal direction nor the lateral direction in plan view was a square but, alternatively, may be a circle or the like.

As being excellent in thermal connectivity with a heating element and exhibiting an excellent heat transport amount during transport of heat of a cooling target, or heating element, even though another component is disposed in the vicinity of the cooling target, or the heating element, the heat sink of the present disclosure is highly useful in a field of cooling of an electronic component with a high heat generation amount installed in a narrow space, such as an electronic component mounted in a server.

What is claimed is:

1. A heat sink comprising:
a container in which a cavity is formed, the container having a first principal surface and a second principal surface opposite the first principal surface;
a working fluid encapsulated in the cavity, and
a steam flow path defined in the cavity and through which the working fluid in a gas phase flows, wherein
the container has a flat portion and a protruding part projecting in an external direction from the flat portion,
an inner space of the protruding part of the container is in communication with an inner space of the flat portion to form the cavity,
the protruding part of the container includes a heat receiver that is to be thermally connected with a heating element that is a cooling target, and
the flat portion of the container has an intermediate portion region continuous from the protruding part and a heat radiator region more distant from the protruding part than the intermediate portion region and thermally connected with a heat radiating fin.

2. The heat sink according to claim 1, wherein the heat radiating fin includes a first heat radiating fin thermally connected with the first principal surface and a second heat radiating fin thermally connected with the second principal surface.

3. The heat sink according to claim 2, wherein the heat radiator region of the container is wider than the protruding part.

4. The heat sink according to claim 2, wherein
the container is in a shape having a longitudinal direction and a lateral direction in plan view,
one end in the longitudinal direction of the container is provided with the protruding part, and
another end in the longitudinal direction of the container is the heat radiator region.

5. The heat sink according to claim 2, wherein
the container is in a shape having a longitudinal direction and a lateral direction in plan view,
a middle portion in the longitudinal direction of the container is provided with the protruding part, and
both ends in the longitudinal direction of the container are each the heat radiator region.

6. The heat sink according to claim 2, wherein
the container has the protruding part in a middle portion of the container in plan view, and
a peripheral portion of the container in plan view is the heat radiator region.

7. The heat sink according to claim 2, wherein
the container is in a shape having a longitudinal direction and a lateral direction in plan view, the longitudinal direction having a bent portion,
the protruding part is provided in each of one end and another end in the longitudinal direction of the container, and
a middle portion in the longitudinal direction of the container is the heat radiator region.

8. The heat sink according to claim 2, wherein
the container includes one plate-shaped body and another plate-shaped body opposite the one plate-shaped body, and
the one plate-shaped body has the protruding part projecting in the external direction.

9. The heat sink according to claim 1, wherein the heat radiator region of the container is wider than the protruding part.

10. The heat sink according to claim 9, wherein the container has a part becoming wider as progress from the protruding part toward the heat radiator region.

11. The heat sink according to claim 10, wherein the container has a part becoming wider as progress from the protruding part toward the heat radiator region.

12. The heat sink according to claim 1, wherein
the container is in a shape having a longitudinal direction and a lateral direction in plan view,
one end in the longitudinal direction of the container is provided with the protruding part, and
another end in the longitudinal direction of the container is the heat radiator region.

13. The heat sink according to claim 1, wherein
the container is in a shape having a longitudinal direction and a lateral direction in plan view,
a middle portion in the longitudinal direction of the container is provided with the protruding part, and
both ends in the longitudinal direction of the container are each the heat radiator region.

14. The heat sink according to claim 1, wherein
the container has the protruding part in a middle portion of the container in plan view, and
a peripheral portion of the container in plan view is the heat radiator region.

15. The heat sink according to claim 1, wherein
the container is in a shape having a longitudinal direction and a lateral direction in plan view, the longitudinal direction having a bent portion,
the protruding part is provided in each of one end and another end in the longitudinal direction of the container, and
a middle portion in the longitudinal direction of the container is the heat radiator region.

16. The heat sink according to claim 1, wherein
the container includes one plate-shaped body and another plate-shaped body opposite the one plate-shaped body, and
the one plate-shaped body has the protruding part projecting in the external direction.
